(19) United States
(12) Patent Application Publication
(10) Pub. No.: US 2003/0178301 A1
(43) Pub. Date: Sep. 25, 2003

(54) Planar magnetron targets having target material affixed to non-planar backing plates

(76) Inventors: David Mark Lynn, Eagle, ID (US); Melvin Marion Clarkson, Boise, ID (US)

Correspondence Address: Angus C. Fox, III, 4501 N. Windsor Drive, Provo, UT, 84604-6303, US

(21) Appl. No.: 10/328,361

(22) Filed: Dec. 23, 2002

Related U.S. Application Data
(60) Provisional application No. 60/343,078, filed on Dec. 21, 2001.

(51) Int. Cl. C23C 14/32

(52) U.S. Cl. 204/298.12

(57) ABSTRACT

Planar magnetron targets are disclosed which include a backing plate which is grooved in the regions where erosion of the target material mainly occurs, thereby permitting greater erosion depth of the target material. The life of the target material may be further extended by employing an in-relief upper surface for the target material. The in-relief surface may be prepared by a number of well-known techniques, which include casting and computer-controlled plasma spray. The target material may be either sprayed on or bonded to the backing plate. For a preferred embodiment of the invention, the backing plate is grooved to create undercut ledges which retain the target material on the backing plate, even if adhesion between the surfaces of the target material and the backing plate material fails as the result of thermal cycling.

### BACKGROUND OF THE INVENTION

This application has a priority date based on Provisional Patent Application No. 60/343,078, filed Dec. 21, 2001.

### FIELD OF THE INVENTION

This invention relates generally to equipment employed for the coating of substrate articles by magnetron sputtering and, more specifically, to the design of planar targets, as well as methods and apparatus for affixing such targets to a target backing plate.

### DESCRIPTION OF THE PRIOR ART

Sputtering is the physical ejection of material from a target as a result of ion bombardment of the target. The ions are usually created by collisions between gas atoms and electrons in a glow discharge. The ions are accelerated into the target cathode by an electric field. A substrate is placed in a suitable location so that it intercepts a portion of the ejected atoms. Thus, a coating is deposited on the surface of the substrate. For at least several decades, sputtering has been the dominant process for the deposition of thin coatings on large-surface-area substrates, such as architectural glass panels, automobile windshields, and the like. Sputtering has also become essential for the production of integrated circuits, which require the step-by-step deposition, masking and etching of many layers, which may include conductive layers, semi-conductive layers, and dielectric layers.

In order to achieve increased sputtering deposition rates, magnetically enhanced targets are widely used. A sputtering device which utilizes a magnetically enhanced target is known as a magnetron. There are two principal types of magnetrons: planar and rotatable cylindrical. Magnetrons of the planar type, which are far less complex and expensive than those of the cylindrical type, were developed first. Rotating cylindrical magnetrons have displaced planar magnetrons for sputtering silicon-containing dielectric compounds such as silicon nitride and silicon dioxide, because of their inherent self-cleaning effect, which eliminates much of the arcing problems brought about by dielectric material buildup during the sputtering process. Nevertheless, planar magnetrons are still widely used for sputtering many materials such as silicon, copper, zinc, silver, gold, magnesium and titanium.

The cathode of a planar magnetron includes an array of permanent magnets arranged in a closed loop and mounted in a fixed position relative to the flat target plate. Thus, the magnetic field is caused to travel in a closed loop, commonly referred to as a “race track”, which establishes the path or region along which sputtering or erosion of the target material takes place. In such a magnetron cathode, the magnetic field confines the glow discharge plasma and increases the length of the path of electrons moving under the influence of the electric field. Magnetic confinement of the plasma greatly enhances the probability of collisions occurring between electrons and gas atoms, thereby greatly increasing the sputtering rate. An additional advantage is that sputtering can be effected using much lower gas pressures than those which are required without magnetic confinement.

Reactive sputtering is a further development that is now widely used to form metal-oxide films. In reactive sputtering, a reactant gas forms a compound with the material which is sputtered from a target plate. When the target plate is a metal, and the reactive gas is oxygen, a metal oxide film is formed on the surface of the substrate.

One of the problems with the targets used in planar magnetrons is that the surface of the target erodes unevenly. The uneven erosion pattern reflects the shape of the magnetic field. FIGS. 1 and 2 are top plan and cross-sectional views, respectively, of a typical unused prior art planar magnetron target 100. The target 100 includes both target material 101 and a backing plate 102, which supports the target material. It will be noted that the target material 101 is a uniformly thick layer, and that it is attached to a planar upper surface 103 of the backing plate 102. After the target 100 is used to the point where it must be discarded, it may assume the appearance of the used target 300 shown in cross-section in FIG. 3. It will be noted that although most of the target material still remains attached to the backing plate 102, any further use of the target 300 would risk eroding the target material 101 to the point where the planar upper surface 103 of the backing plate 102 would be exposed.

Another problem with the targets used in planar magnetrons is that the backing plate 102 may have thermal expansion characteristics which are dissimilar to those of the target material. In such a case, thermal cycling can cause the target material 101 to detach from the backing plate 102. Such an event may constitute an unrecoverable manufacturing occurrence, which would require either the discarding or reworking of the substrate.

What is needed is are new planar magnetron targets which eliminate the heretofore described problems associated with the prior art targets.

### SUMMARY OF THE INVENTION

Several improved planar magnetron targets, which eliminate the first noted problem by permitting the target to be used for much longer periods, include a backing plate which is grooved in the regions where erosion of the target material mainly occurs, thereby permitting greater erosion depth of the target material.

The life of the target material may be further extended by employing an in-relief upper surface for the target material. The in-relief surface may be prepared by a number of well-known techniques, which include casting and computer-controlled plasma spray. The target material may be either sprayed on or bonded to the backing plate.

Several embodiments of improved planar magnetron targets are disclosed which eliminate both the first and second noted problems typically associated with prior-art planar magnetron targets. The backing plate is grooved to create undercut ledges which retain the target material on the backing plate, even if adhesion between the surfaces of the target material and the backing plate material fails as the result of thermal cycling.

### BRIEF DESCRIPTION OF THE DRAWINGS

FIG. 1 is a top planar view of a prior art planar magnetron target;

FIG. 2 is a cross-sectional view of the planar magnetron target of FIG. 1, taken through section line 2-2;

FIG. 3 is a cross-sectional view of the planar magnetron target of FIG. 1 and FIG. 2 following sputtering, which has rendered the target unuseable;

FIG. 4 is a top planar view of a first embodiment improved planar magnetron target;

FIG. 5 is a cross-sectional view of the planar magnetron target of FIG. 4, taken through section line 5-5;

FIG. 6 is a cross-sectional view of the planar magnetron target of FIG. 4 and FIG. 5 following sputtering, which has rendered the target unuseable;

FIG. 7 is a is a top planar view of a second embodiment improved planar magnetron target, which includes a shaped sputtering surface;

FIG. 8 is a cross-sectional view of the planar magnetron target of FIG. 7; taken through section line 8-8;

FIG. 9 is a top planar view of a third embodiment planar magnetron target, which employs a racetrack magnetic plasma confinement configuration, and which incorporates a first material lock-in feature;

FIG. 10 is a cross-sectional view of the third embodiment planar magnetron target of FIG. 9, taken through section line 10-10 thereof;

FIG. 11 is a cross-sectional view of a fourth embodiment planar magnetron target that is similar to that of FIGS. 9 and 10, but which has a first alternative target material lock-in feature; and

FIG. 12 is a cross-sectional view of a fifth embodiment planar magnetron target that is similar to that of FIGS. 9 and 10, but which has a second alternative target material lock-in feature.

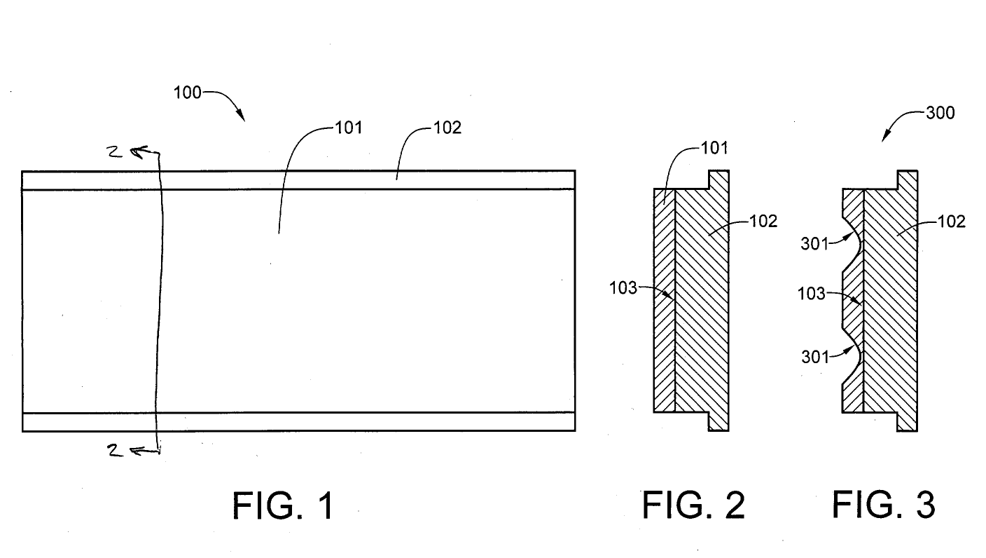

### PREFERRED EMBODIMENT OF THE INVENTION

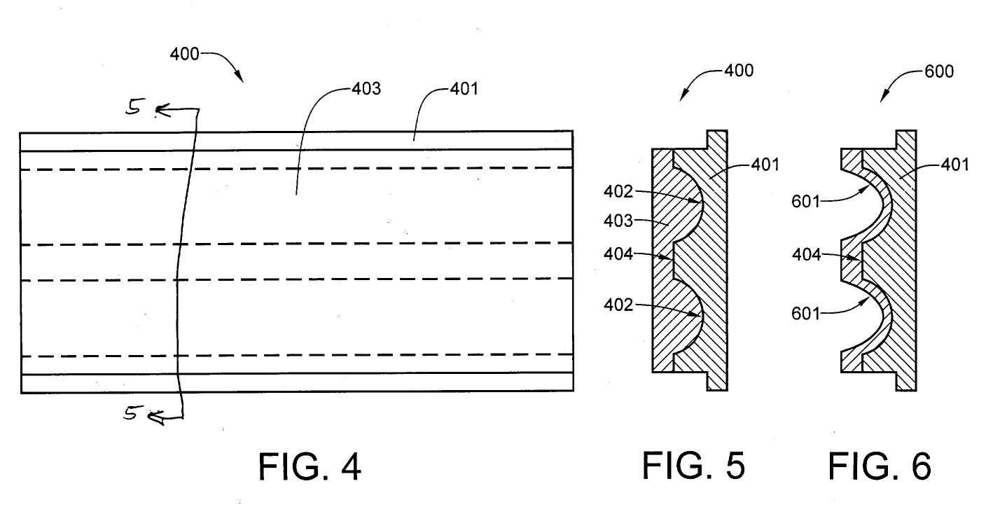

Multiple embodiments of an improved planar magnetron target are disclosed herein. Some of the embodiments solve only the problem of short target life, while the others solve not only the problem of short target life, but also the detachment problem, whereby the bond between the target material and the backing plate fails from thermal cycling. The various embodiments of the improved planar magnetron target will now be described in detail, with reference to the attached drawing FIGS. 4 through 11.

Referring now to FIGS. 4 and 5, a first a first embodiment improved planar magnetron target 400 includes a backing plate 401 which incorporates a groove 402 of substantially semicircular cross section in each region where the plasma is magnetically confined. The target material 403 is applied such that the grooves are completely filled therewith. This design affords a much greater effective depth of target material, as the erosion of the target material in the confined plasma regions of the target material may continue well below the face 404 of the backing plate.

After the target of FIG. 5 is used to the point where it must be discarded, it may assume the appearance of the used target 600 of FIG. 6.

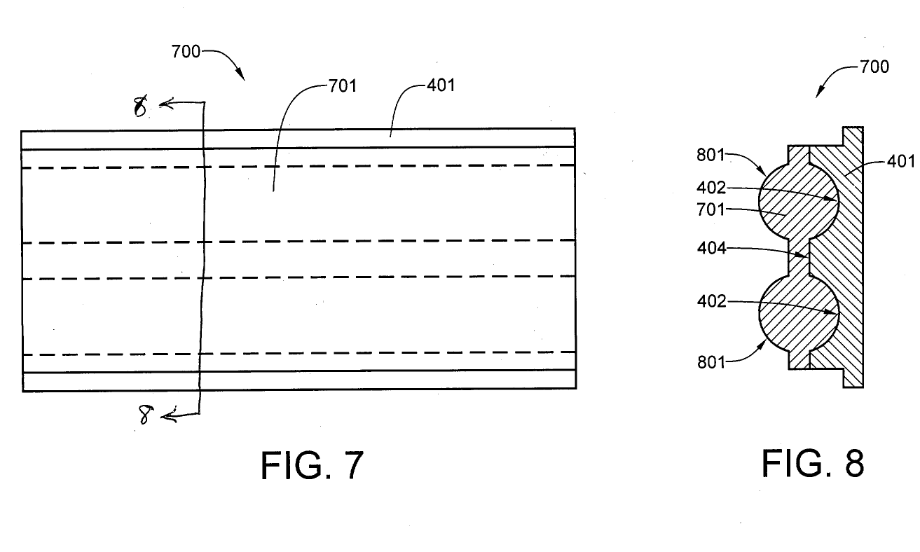

Referring now to FIGS. 7 and 8, a second embodiment improved planar magnetron target 700 incorporates the grooved backing plate 401 of the first embodiment target 400, but add the additional feature of a target material layer 701 that is formed in relief. The shaped surface 801 may be formed using casting techniques or computer-controlled plasma spraying.

For either the first and second embodiments of the improved planar magnetron targets 400 and 700, respectively, the target material may be either sprayed, bonded or cast onto the backing plate.

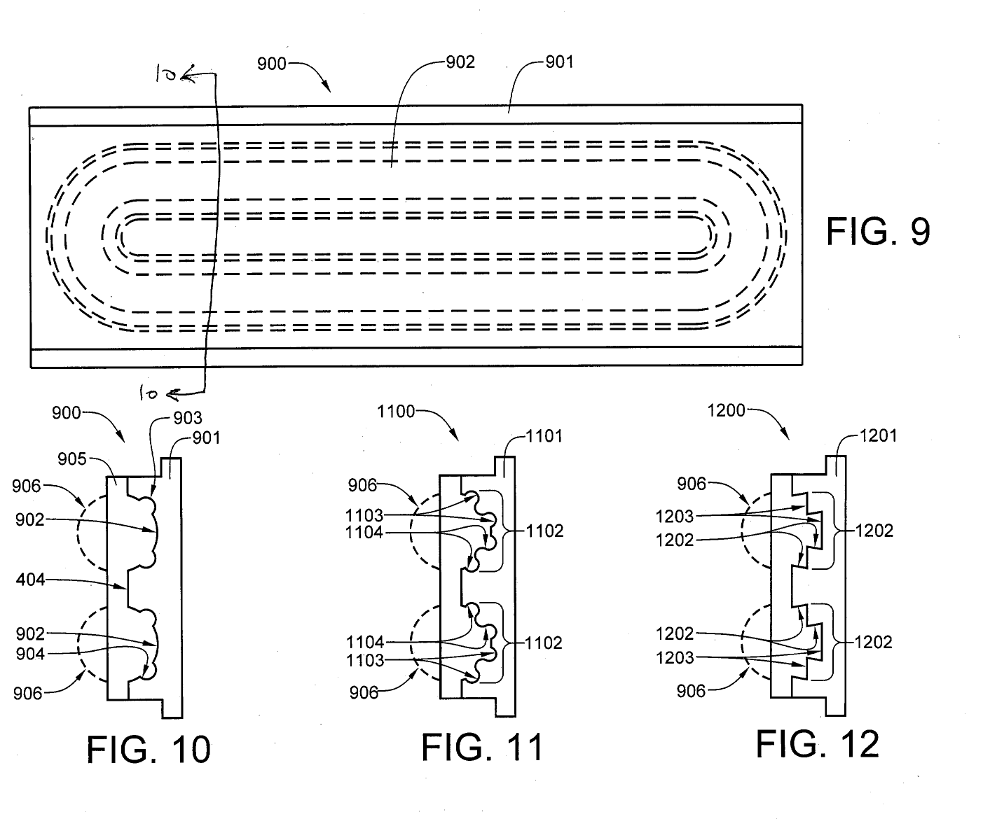

Referring now to FIGS. 9 and 10, a third embodiment improved planar magnetron target 900 includes a backing plate 901 which incorporates a racetrack-shaped grooves 902, which provide enhanced target life through the creation of a target material layer have greater thickness in the regions where target material erosion is intended to occur. In addition, each of the primary grooves 901 incorporates a pair of secondary semicircular grooves 903 which provide a pair of undercut ledges 904. These undercut ledges 904 retain the target material 905 in place on the backing plate 901, even in cases when the bond between the backing plate 901 and the target material layer 905 completely fails. The dashed lines 906 indicate that in-relief target material may also be used for this embodiment. This is also true of the fourth and fifth embodiments which follow.

Referring now to FIG. 11, the fourth embodiment planar magnetron target 1100, as compared to the third embodiment target 900, includes a backing plate 1101 having four secondary semicircular grooves 1003 for each primary groove 1102, each secondary groove 1103 forming a target-material-securing undercut ledge 1004.

Referring now to FIG. 12, the fifth embodiment planar magnetron target 1100 includes a backing plate 1201 having primary grooves 1202 formed by steps 1203. The front of each step 1202 is undercut, which assists in the retention of the target material.

The backing plates of the various embodiments of the improved planar magnetron targets described heretofore may be manufactured from any one of a number of conventional metals currently in use, such as aluminum, aluminum alloys, steel, stainless steel, and copper. The target material may include any of the target materials presently used in the sputtering industry.

Although only several embodiments of the improved planar magnetron targets are disclosed herein, it will be obvious to those having ordinary skill in the art that changes and modifications may be made thereto without departing from the scope and the spirit of the invention.

What is claimed is:

1. A magnetron target having a backing plate which is grooved in the regions where erosion of the target material mainly occurs, thereby permitting greater erosion depth of the target material.

2. The magnetron target of claim 1, wherein the target material is further extended by employing an in-relief upper surface for the target material.

3. The magnetron target of claim 2, wherein the in-relief surface is prepared by casting.

4. The magnetron target of claim 2, wherein the in-relief surface is prepared by computer-controlled plasma spray.

5. The magnetron target of claim 3, wherein the target material is bonded to the backing plate.

6. The magnetron target of claim 1, wherein the backing plate is grooved to create undercut ledges which retain the target material on the backing plate, even if adhesion between the surfaces of the target material and the backing plate material fails as the result of thermal cycling.
